(19) United States
(12) Patent Application Publication
(10) Pub. No.: US 2015/0062998 A1
(43) Pub. Date: Mar. 5, 2015

(54) PROGRAMMABLE MEMORY

(71) Applicant: Sang Woo NAM, Cheongju-si (KR)

(72) Inventor: Sang Woo NAM, Cheongju-si (KR)

(73) Assignee: DONGBU HITEK CO., LTD., Seoul (KR)

(21) Appl. No.: 14/261,014

(22) Filed: Apr. 24, 2014

(30) Foreign Application Priority Data
Sep. 4, 2013 (KR) 10-2013-0105941

(51) Int. Cl. G11C 17/16; H01L 27/112

(52) U.S. Cl. CPC G11C 17/16; H01L 27/11206
USPC 365/96; 257/379; 438/238

(57) ABSTRACT

A programmable memory is provided. The programmable memory has a select transistor that includes a gate, a source, and a drain. An anti-fuse device is connected to a drain region of the select transistor. The anti-fuse device includes a dielectric layer on an upper substrate of the drain region, a polysilicon layer on the dielectric layer, and an anti-fuse electrode line in contact with the drain region. The dielectric layer breaks down and the anti-fuse device is programmed when the select transistor is turned on and a high voltage is applied through the anti-fuse line.

### CROSS-REFERENCE TO RELATED APPLICATIONS

The present application claims priority under 35 U.S.C. 119 and 35 U.S.C. 365 to Korean Patent Application No. 10-2013-0105941 (filed on Sep. 4, 2013), which is hereby incorporated by reference in its entirety.

### BACKGROUND

The present disclosure relates to a one-time programmable memory, and more particularly, to a memory device configured to enable easy dielectric breakdown of an anti-fuse device.

Until now, anti-fuse devices have been used in manufacturing a complementary metal-oxide-semiconductor (CMOS) one-time programmable (OTP) non-volatile memory. Anti-fuse devices generally perform the opposite function of a fuse. In a normal state, the anti-fuse is an open electrical circuit. When a high voltage is applied to the anti-fuse, the dielectric material therein breaks down, and the anti-fuse closes the circuit. An OTP read-only memory (ROM) can be implemented using these two states of an anti-fuse.

FIG. 1 is a circuit diagram of an exemplary memory cell according to embodiments of the present invention.

The memory cell of FIG. 1 is an OTP ROM device that stores data when an oxide of the gate of a memory transistor 12 breaks down. A select transistor 10 configured to select a corresponding cell and a memory transistor 12 is connected to an active region.

By applying a high voltage to a bit line during programming and turning on the select transistor 10 to allow a junction bias to be grounded, a high potential is applied to a dielectric layer in the memory transistor 12 and, accordingly, the dielectric layer of the memory transistor 12 is broken down.

However, since such a related art structure turns on the select transistor 10 with a high voltage to connect it to the ground, programming is complex. In addition, since turn-on of the anti-fuse is performed by breaking down the dielectric layer in a junction-overlapped region of the memory transistor 12, a large amount of current may leak out to the substrate.

### SUMMARY

Embodiments of the present invention provide a memory device, where a stable dielectric breakdown and/or anti-fuse may occur by applying a high voltage through a contact region.

According to some embodiments of the present invention, a programmable memory includes a select transistor including a gate, a source, and a drain region, and an anti-fuse device connected to the drain region of the select transistor, where the anti-fuse device includes a dielectric layer on an upper surface of the drain region, a polysilicon layer on the dielectric layer, and a first electrode coupled to and/or in contact with the drain region.

When the select transistor is turned on and the anti-fuse device is programmed, the dielectric is broken down by applying a high voltage to the first electrode and/or an anti-fuse line.

The details of one or more embodiments are set forth in the accompanying drawings and the description below. Other features will be apparent from the description and drawings, and from the claims.

### BRIEF DESCRIPTION OF THE DRAWINGS

FIG. 1 is a circuit diagram of a related art memory cell.

FIG. 2 is a view illustrating a cross-sectional structure of an exemplary programmable memory according to one or more embodiments of the present disclosure.

FIG. 3 is a unit cell circuit diagram of an exemplary memory according to embodiments of the present disclosure.

FIG. 4 is a view illustrating a planar structure of an exemplary programmable memory according to one or more embodiments of the present disclosure.

FIG. 5 is a view illustrating an array configuration of an exemplary programmable memory according to embodiments of the present disclosure.

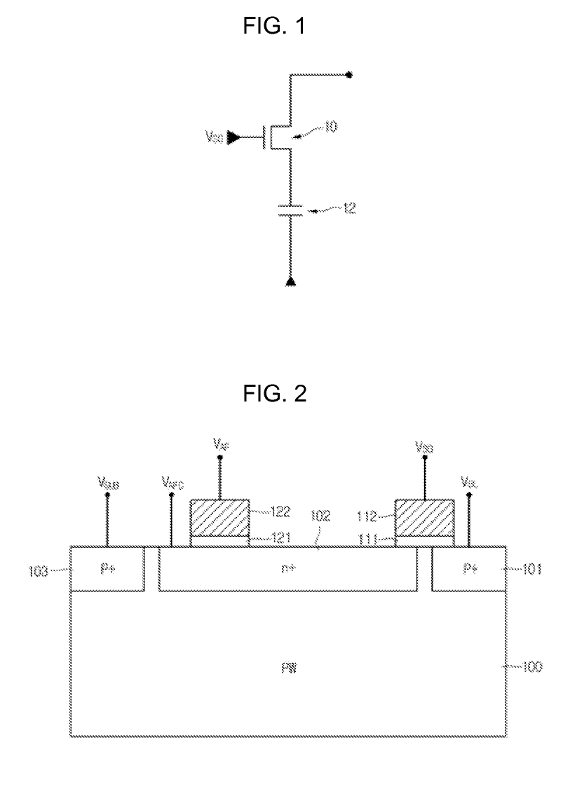

### DETAILED DESCRIPTION OF THE EMBODIMENTS

Reference will now be made in detail to embodiments of the present disclosure, examples of which are illustrated in the accompanying drawings.

A programmable device according to one or more embodiments will be described in detail with reference to the accompanying drawings. The invention may, however, be embodied in many different forms and should not be construed as being limited to the embodiments set forth herein; rather, that alternate embodiments falling within the spirit and scope of the present disclosure can easily be derived through adding, altering, and changing, and will fully convey the concept of the invention to those skilled in the art.

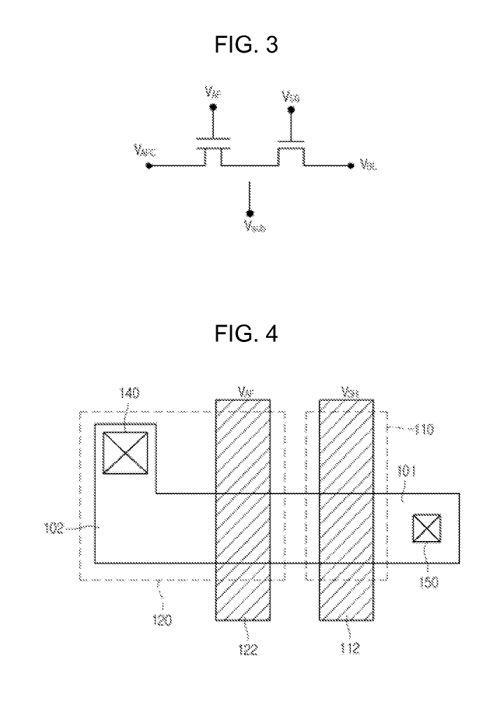

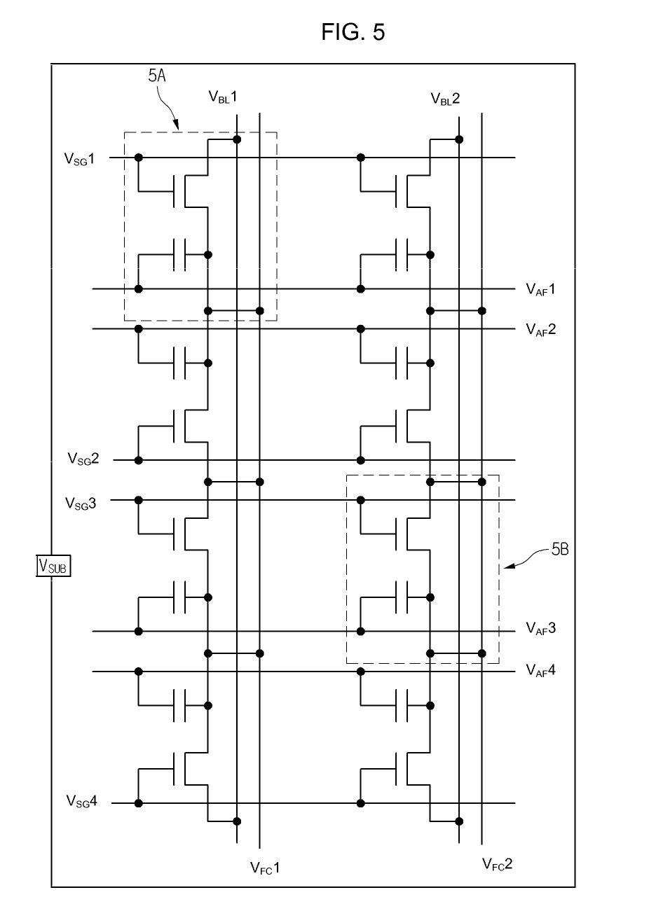

FIG. 2 is a view illustrating a cross-sectional structure of an exemplary programmable array according to one or more embodiments of the present disclosure, and FIG. 3 is a unit cell circuit diagram of an exemplary memory according to embodiments of the present disclosure, FIG. 4 is a view illustrating a planar structure of an exemplary programmable memory according to one or more embodiments of the present disclosure, and FIG. 5 is a view illustrating an array configuration of an exemplary programmable array according to one or more embodiments of the present disclosure.

In the description below, the term “MOS” is used to refer to all structures of a field effect transistor (FET), a metal insulator semiconductor (MIS) transistor, a half transistor, a capacitor, and a unit cell of a programmable memory. According to embodiments of the present disclosure, the unit cell of a programmable memory may include one transistor and one capacitor, and the transistor and capacitor are respectively referred to as a select transistor and an anti-fuse device.

An exemplary memory structure according to embodiments of the present disclosure is described in relation to FIGS. 2 and 3. In FIG. 2, an NMOS type memory device is shown, although a PMOS type memory device may also be used to form a select transistor and an anti-fuse device on a substrate into which N-type impurities are injected, according to one or more embodiments.

Referring to FIGS. 2 and 3, in the case of an NMOS type memory device, a substrate 100 having P-type impurities injected therein includes a source region 101 having n-type impurities injected therein configured as a first diffusion region, and a drain region 102 having n-type impurities injected therein configured as a second diffusion region. In addition, although not shown in the drawing, the source and drain regions 101 and 102 may further include a lightly doped drain (LDD) structure.

Furthermore, a select transistor 110 (FIG. 4) is configured to connect a bit line (e.g., BL or V_{BL}) to the anti-fuse device 120. The select transistor 110 further includes a dielectric layer 111 (e.g., a gate oxide) and a polysilicon layer 112 configured to form a gate electrode. Optionally, a select line (e.g., V_{SG}) is electrically connected to the gate electrode 112, which may partially overlap with the source region 101 and the drain region 102.

In addition, an anti-fuse device 120 is on or over the drain region 102 and includes a dielectric layer 121 that breaks down during programming and a polysilicon layer 122 on the dielectric layer 121 electrically connected to an anti-fuse control line (e.g., V_{AF}). The anti-fuse device 120 may include a half transistor or a capacitor in which polysilicon electrode 122 has the same composition and thickness and breakdown voltage as polysilicon layer 112, and capacitor dielectric 121 has substantially the same composition and the same or similar thickness as gate oxide 111. The anti-fuse device 120 and the select transistor 110 may share the drain region 102, which is configured as a diffusion region. The drain region 102 may be in contact with an anti-fuse contact 140 (FIG. 4), which may be or be connected to an anti-fuse programming line (V_{AFC}) and/or voltage. The anti-fuse contact 140 and/or drain region 102 are configured as a bottom electrode programming terminal of the anti-fuse device 120.

Although not shown in the drawings, side wall spacers may be on both sides of the polysilicon layers 112 and 122. CMOS processing steps such as diffusion for a thinly doped layer or silicidation of diffusion and gate regions may be applied. Moreover, a p-type impurity doping region 103 may be on one side of the drain region 102 and may contact a substrate bias supply line and/or voltage V_{sub} to apply a substrate voltage. The p-type regions 101 and 103 may be formed simultaneously.

In particular, the anti-fuse programming (V_{AFC}) line in contact with the drain region 102 is configured to selectively provide a high voltage for breaking down the dielectric layer 121 of the anti-fuse device 120. When a high voltage is applied to the bit line (V_{BL}) for programming, an additional voltage may also be applied through the diffusion region 102 and/or anti-fuse contact 140 (or the V_{AFC} line). According to some embodiments, the breakdown of the dielectric layer 121 of the anti-fuse device 120 may only be initiated through the diffusion region 102 and/or the V_{AFC} line. Here, the V_{AFC} line connected to the anti-fuse device may also be referred to as an anti-fuse electrode line.

A programming operation for an OTP memory device in accordance with the present disclosure is now described.

For programming, 0V (e.g., a ground voltage) is applied to the anti-fuse contact 140 and a high voltage is applied to V_{AF} line and/or polysilicon layer 122 to form a high voltage differential across the anti-fuse dielectric 121 (i.e., greater than the breakdown voltage of the dielectric layer 121) and break down the dielectric layer 121. At this time, 0V is applied to the select transistor to turn the select transistor off, and the V_{BL} electrode line, which is the bit line, is grounded or left floating in order to prevent or inhibit current flow.

In this case, since it is not necessary to apply a voltage through the V_{BL} line that is in contact with the source region 101, the amount of current leaking to the substrate may be significantly or substantially reduced compared to the amount of current when a high voltage is applied to the V_{BL} line.

According to some embodiments, a high voltage is applied to the anti-fuse programming (e.g., V_{AFC}) line and a predetermined voltage is applied to the V_{SG} line and/or select gate 112 during programming. The select transistor is turned on, and 0V is applied to the bit line (e.g., the V_{BL} line). The ground voltage or 0V is also applied to the V_{AF} line and/or the upper anti-fuse electrode 122, which may cause a current to flow from the contact 140 and/or a high voltage differential across the anti-fuse dielectric 121 to enable breakdown of the dielectric layer 121.

FIG. 5 illustrates an exemplary memory array configuration according to embodiments of the present invention. According to FIG. 5, a cell region may be selected for programming by applying a voltage to the V_{SG} line and the V_{BL} line.

In addition, the anti-fuse device may operate as a resistor by breaking down an oxide (e.g., a dielectric layer) of a capacitor (e.g., an anti-fuse device) in the specified cell region and applying a high voltage to the anti-fuse region through the programming (e.g., V_{AFC}) line. When the dielectric layer of each of the anti-fuse devices breaks down in cell regions 5A and 5B (among the 8 cells shown in FIG. 5), only the anti-fuse devices (e.g., capacitors) for the corresponding two cells function as resistors. In other cells, the capacitors still function as capacitors. For example, in order to read the programmed memory device, when the select transistor 110 is turned on (e.g., by applying a predetermined voltage to the V_{SG} line and a predetermined voltage to the V_{AF} line and the V_{BL} line), current flows only through the programmed cells 5A and 5B. Therefore, the value is read as ‘0’. In addition, for the other cell regions, since the anti-fuse devices do not function as resistors, current does not flow. Therefore, the value is read as ‘1’.

According to embodiments of the present invention, a memory device can be implemented by adding a line contacting a drain region, which may be a diffusion region, to an anti-fuse transistor structure. Accordingly, precise programming is possible without enlarging the area of the microfabricated device structure.

Furthermore, since a gate oxide of the anti-fuse device can directly break down by contacting a diffusion region, programming operations can be simple and precise.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings, and the appended claims. In addition to variations and modifications in the component parts and/or arrangements, alternative uses will also be apparent to those skilled in the art.

What is claimed is:

1. A programmable memory comprising:
a select transistor comprising a gate, a source, and a drain region; and
an anti-fuse device connected to the drain region of the select transistor,
wherein the anti-fuse device comprises a dielectric layer on an upper surface of the drain region, a polysilicon layer on the dielectric layer, and a first electrode in contact with the drain region.

2. The programmable memory of claim 1, wherein the dielectric layer breaks down when a high voltage is applied to the first electrode and the select transistor is turned on.

3. The programmable memory of claim 1, further comprising a bit line in electrical contact with the source, and the dielectric layer breaks down when a high voltage is applied to the bit line and the first electrode, and the select transistor is turned on.

4. The programmable memory of claim 1, wherein the select transistor and the anti-fuse device share the drain region.

5. The programmable memory of claim 1, wherein the gate of the select transistor comprises a polysilicon layer, and the select transistor further comprises a gate oxide between the gate and a substrate including the source and the drain region.

6. The programmable memory of claim 5, wherein the polysilicon layer of the anti-fuse device has a same composition and a same thickness as the gate.

7. The programmable memory of claim 1, wherein the drain region comprises an anti-fuse contact region and the programmable memory further comprises a contact between the anti-fuse contact region and a programming line.

8. The programmable memory of claim 7, wherein the programming line, the anti-fuse contact, and the drain region are configured to provide a programming voltage and/or current to the anti-fuse device.

9. The programmable memory of claim 8, further comprising a bit line configured to transmit a voltage from the anti-fuse device, wherein the select transistor is electrically connected to the bit line.

10. The programmable memory of claim 1, wherein the source is configured as a first diffusion region having a first conductivity type.

11. The programmable memory of claim 10, wherein the drain region is configured as a second diffusion region having a second conductivity type.

12. A programmable memory array, comprising the programmable memory of claim 1 and a plurality of additional, substantially identical programmable memories electrically connected together in rows and columns.

13. A method of making a programmable memory, comprising:
forming a source having first conductivity-type impurities and a drain region having second conductivity-type impurities in a substrate having first conductivity-type impurities;
forming a dielectric layer on the substrate;
forming a polysilicon layer on the dielectric layer
patterning the polysilicon layer and the dielectric layer to form (i) a gate electrode of a select transistor overlapping the source and the drain region and (ii) an electrode of an anti-fuse device over the drain region.

14. The method of claim 13, further comprising forming an impurity doping region in the substrate on one side of the drain region configured to applying a bias to the substrate.

15. The method of claim 13, further comprising forming a contact that is electrically connected to the drain region.

16. A method of programming a programmable memory, comprising:
applying a relatively high voltage to one of an anti-fuse contact region or a polysilicon upper electrode of an anti-fuse device, the anti-fuse device further comprising (i) a dielectric layer on an upper surface of a drain region electrically connected to a select transistor and the anti-fuse contact region, and (ii) the polysilicon upper electrode on the dielectric layer; and
applying a ground voltage to the other of the anti-fuse contact region or the polysilicon upper electrode of the anti-fuse device to breakdown the dielectric layer of the anti-fuse device.

17. The method of claim 16, wherein the relatively high voltage is applied to the anti-fuse contact region, the ground voltage is applied to the polysilicon upper electrode, and the select transistor is turned on.

18. The method of claim 16, wherein the relatively high voltage is applied to the polysilicon upper electrode, the ground voltage is applied to the anti-fuse contact region, and the select transistor is turned off.
